(19) United States
(12) Patent Application Publication
(10) Pub. No.: US 2020/0286764 A1
(43) Pub. Date: Sep. 10, 2020

(54) HIGH RESOLUTION STAGE POSITIONER

(71) Applicant: ONTO INNOVATION, INC., Wilmington, MA (US)

(72) Inventor: J. Casey DONAHER, Westford, MA (US)

(73) Assignee: ONTO INNOVATION, INC., Wilmington, MA (US)

(21) Appl. No.: 16/650,851

(22) PCT Filed: Sep. 13, 2018
(86) PCT No.: PCT/US2018/050788

§ 371 Date: Mar. 25, 2020

Related U.S. Application Data
(60) Provisional application No. 62/565,951, filed on Sep. 29, 2017.

(51) Int. Cl. H01L 21/68; H02K 11/21; H02K 41/03

(52) U.S. Cl. CPC H01L 21/68; H02K 2201/18; H02K 41/03; H02K 11/21

(57) ABSTRACT

A mechanism for localizing a substrate relative to a projection camera or other apparatus over large travel distances is described. The mechanism includes one or more trucks that move with the stage in a primary direction and remain stationary when the stage moves in an ancillary direction. The position of the trucks, together with relative distances between the truck(s) and a stage on which the substrate is supported facilitates alignment.

### CROSS-REFERENCE TO RELATED APPLICATIONS

This application claims the benefit of U.S. Provisional Patent Application No. 62/565,951, filed Sep. 29, 2017, which is incorporated herein by reference in its entirety.

### TECHNICAL FIELD OF THE INVENTION

The present invention relates generally to motion control and positioning of stages used in semiconductor fabrication.

### INTRODUCTION

Controlling the accuracy and precision of the positioning of a substrate relative to a mechanism that acts upon that substrate is a difficult and frankly expensive endeavor. This is particularly so when the positioning must take place over a large region and long travel.

In the field of semiconductor manufacturing it is customary to use interferometers, laser or broadband, to accurately position a substrate and the stage or carrier on which it is supported. However interferometers used to position a substrate generally have a measurement leg that extends through open air. Where extreme accuracy or large travel distances are desired, the variability of the index of refraction of air through which the measurement leg of an interferometer passes can negatively affect the position of the substrate. Accordingly, there is a need for a less variable means of determining and/or controlling the position of a substrate.

What is more, even if an interferometer can be arranged such that there is little or no variation in the index of refraction of air through which the measurement leg of the interferometer passes, the optical components necessary to create and install an interferometer are expensive. This expense is even greater where the travel of the substrate or a stage on which the substrate is supported is large. For example, mirrors used at the terminus of the measurement leg tend to extend along an axis of travel of a stage so that the position of the stage may be determined continuously. Where the stage is quite large, an optically flat mirror of suitable size is both large and very expensive. Accordingly, there is a need for a mechanism that can be used to measure and/or control large translations of a stage, which also uses relatively small and inexpensive components.

### BRIEF DESCRIPTION OF THE DRAWINGS

FIG. 1 is a schematic elevation of a lithography machine that may incorporate the present invention.

FIG. 2 is a schematic plan view of a pair of traveler mechanisms employed to locate a stage relative to a platen on which the stage travels.

FIG. 3A is a schematic elevation of a traveler mechanism in which a rail is positioned between a stage and a platen.

FIG. 3B is a schematic elevation of a traveler mechanism in which a rail is positioned above a stage.

FIG. 3C is a schematic elevation of another traveler mechanism in which a rail is positioned above a stage.

FIGS. 4A and 4B show the travel and size of a stage relative to one and two projection cameras or other apparatus, respectively.

### DETAILED DESCRIPTION

In the following detailed description of the invention, reference is made to the accompanying drawings that form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof.

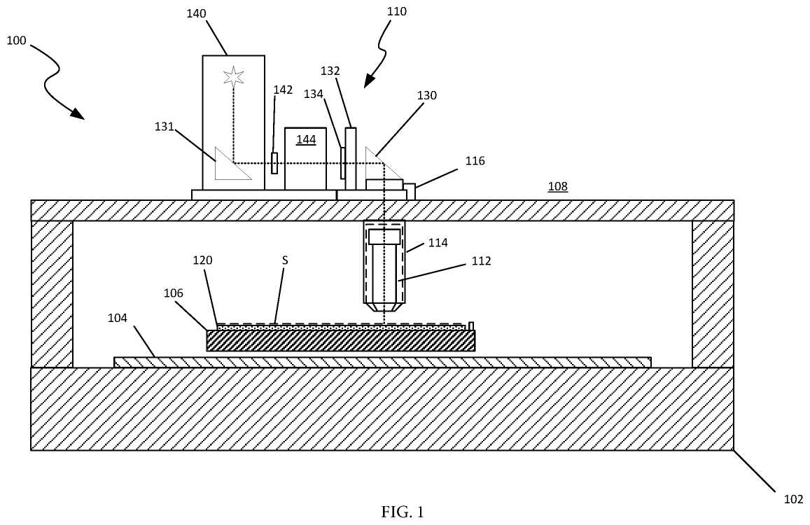

FIG. 1 is a diagram of a lithography machine 100 in which the principles of the present invention may be employed. The lithography machine 100 includes a base 102, which is typically a large block of finished granite that sits on isolation supports (not shown). The combination of the large mass of the base 102 and the design of the isolation supports provides isolation of the lithography machine 100 from floor vibrations. The isolation supports also prevent machine forces from getting into the factory floor and disturbing nearby machinery. The base 102 and isolation supports may be constructed from common commercial parts and materials.

On top of the base 102 is a large grid motor platen 104, such as one disclosed in U.S. Pat. No. 5,828,142, hereby incorporated by reference. The large grid motor platen 104 may include a matrix of soft iron teeth of 1 mm square, separated in X and Y directions by a 1 mm gap. The gaps between all teeth are filled with non-magnetic material, usually epoxy. This surface is ground very flat, to tolerances of a few microns, to provide an air bearing quality surface. Flatness is also useful to control tip and tilt of a main X, Y, Θ stage 106 (hereafter referred to as the main stage 106), a possible source of Abbe offset errors in a stage interferometer system.

The area covered by the grid motor platen 104 is large enough to allow the main stage 106 to move to all required positions. The travel area allows movement to a substrate exchange position (at the machine front), to substrate alignment location(s), to all calibration locations, and throughout an exposure area. The travel area for the embodiment described herein correlates to the size of a substrate carried on the stage 106.

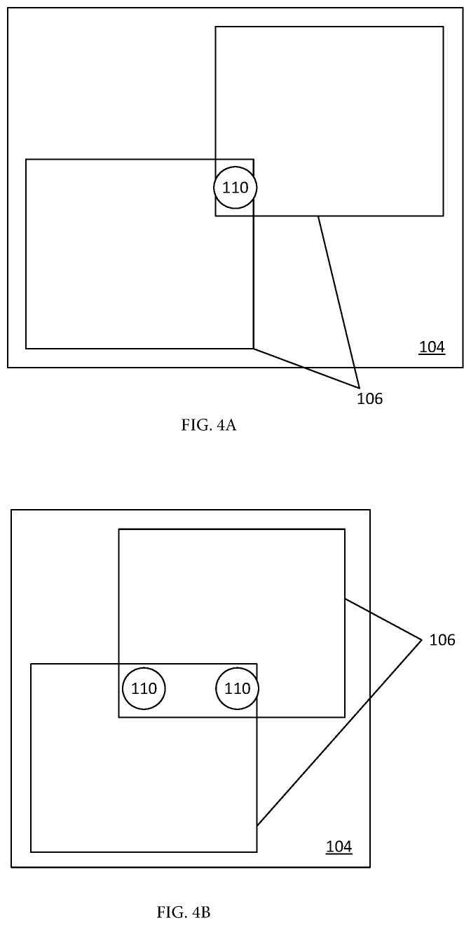

As in FIG. 4A, where a single projection camera or other process apparatus is provided, the lateral extents of the base 104 will be on the order of twice the lateral extents of the substrate S so that the projection camera/apparatus can address the entire substrate. In another embodiment such as the one in FIG. 4B wherein two projection cameras or other process apparatus are provided, the base 104 will have a lateral extent of approximately 1.5× the corresponding lateral extents of the substrate S. This allows two projection cameras/apparatuses to address the entire substrate S, each camera/apparatus covering approximately one-half of the substrate S.

In embodiments where substrates such as disc shaped silicon wafers are carried by the stage 106, the travel of the stage is, at a minimum, comparable to the lateral extents of the substrate (25 mm to 450 mm), plus a bit more to allow for substrates to be placed onto and removed from the stage 106. Large panels of glass, silicon, or composite materials used in the packaging of semiconductor devices and in the formation of large screens may also be carried by suitably sized stages 106. Table 1 below identifies common panel sizes. Additional panel sizes and aspect ratios are contemplated.

| | Length [mm] | Width [mm] |
|---|---|---|
| GEN 1 | 300 | 400 |
| GEN 2 | 370 | 470 |
| GEN 3 | 550 | 650 |
| GEN 3.5 | 600 | 720 |
| GEN 4 | 680 | 880 |
| GEN 4.5 | 730 | 920 |
| GEN 5 | 1100 | 1250-1300 |
| GEN 6 | 1500 | 1800-1850 |
| GEN 7 | 1870 | 2200 |
| GEN 7.5 | 1950 | 2250 |
| GEN 8 | 2160 | 2460 |
| GEN 10 | 2880 | 3130 |
| GEN 10.5 | 2940 | 3370 |

The stage 106, in one embodiment, has within its body four forcer motors (not shown). These motors are arranged to drive the stage across the grid motor platen 104. Two motors are oriented to drive the main stage 106 in an X-axis (“X”) direction. Two additional motors are oriented at 90° to drive the main stage 106 in a Y-axis (“Y”) direction. Either or both pairs of motors may be driven differentially to provide small rotation motion (Θ). In this manner, the main stage 106 may be controlled to move in a very straight line even though the tooth pattern in the grid motor platen 104 may not be straight. Note the present invention is not limited to planar or “Sawyer” type motors. Ball screws, linear actuators of various types, piezo electric actuators or any other suitable motor or actuator that can move the stage 106 relative to a mechanism that acts upon a substrate S may be used.

In FIG. 1 the stage 106 is shown as having a chuck 120 mounted thereon. The illustrated chuck 120 has a form factor adapted to support a substrate S that is a panel of the basic size/shape described in Table 1. As described in U.S. Pat. No. 7,385,671, the chuck 120 may have substituted therefore different numbers or types of chucks adapted to hold different substrates such as silicon wafers. U.S. Pat. No. 7,385,671 is hereby incorporated by reference.

A stiff bridge structure 108 supports a projection camera 110 above the main stage 106. The projection camera 15 has a projection lens 112, of approximately 2× (i.e., two times) reduction, mounted in a lens housing 114. The lens housing 114 is mounted on two Z-axis (vertical) air bearings, not shown. These air bearings may be commercially purchased and are preferably a box journal style, which are very stiff. This Z-axis motion is used to move the lens housing 114 and projection lens 112 up and down over small distances needed for focus. The projection lens 112 is telecentric at its image side, so that small changes in focus do not cause image size or image placement errors. Note that other optical arrangements and magnifications are contemplated.

The projection lens housing 114 has an individual, real-time, auto-focus sensor (not shown) attached to its bottom. These sensors use simple optics to transform a laser diode light source into a focused slit of light at a substrate S. Some of the light from this slit reflects off the substrate S and is captured by a receiving side of the real-time auto-focus sensor. The reflected slit light is imaged by the receiving optics onto a linear CCD array (not shown). Image processing software is used to locate the image of the reflected slit on the CCD array. Any shift in the position of the image of the reflected slit is then used to control Z-axis drive 116 for projection camera 110, until the position of the image on the CCD array is restored. In this manner, the “focus” of projection camera 110 is maintained at a constant gap. During machine construction, the motion of the Z-axis in micrometers is used to determine the motion of the image on the CCD array in pixel units. This calibration permits conversion of subsequent focus offsets to be implemented as pixel offsets in the Z-axis focus control system.

Attached to the top of the lens housing 114 is a fold mirror 130. This mirror 21 puts the remainder of the projection camera 110 off to the right side. In this embodiment, the projection lens 112 is designed to have a long working distance at its object side to permit use of the fold mirror 130. Note that by the omission of fold mirrors from the projection camera 110, a straight optical path may be achieved. Fold mirrors having different orientations may also be used to further form the optical path of the projection camera 110 to meet whatever space requirements that exist.

Projection camera 110 has its own 6-axis reticle chuck 132, which holds a reticle 134 that includes the pattern or mask being imaged onto the respective substrate. The reticle 134 may be referred to as an image source. It should be understood that other devices may also be used as image sources, such as a multi-mirror light valve or an LCD light valve that dynamically generates a mask (i.e, a maskless image source).

Illumination for the lithography exposure is provided by a lamp house 140 that encloses a mercury lamp that in one embodiment outputs about 3500 watts power. The light within the lamp house 140 is collected, focused, and filtered, and then exits the lamp house 140 near a shutter 142. Note that as shown, the lamp house 140 includes a fold mirror 131 that allows the optical path of the projection camera 110 to be made more compact. The folded arrangement of the projection camera 110 illustrated in FIG. 1 is only one configuration of many that can be or are commonly used.

When the shutter 142 is opened, light from the lamp house 140 passes through a condenser lens assembly 144, through the reticle 134, through projection lens 112, and exposes the substrate S with the image imposed by the reticle 134. As is well understood, the substrate S is coated with a photo-sensitive resistive coating. A dose sensor (not shown) may be part of the shutter 142.

The foregoing description is of a stepper type configuration for a lithography system. Other configurations such as scanners, imprint, and direct write lithography systems are well known and may benefit from the application of the present invention. What is more, while the present invention is particularly useful in lithography applications, it is not so limited.

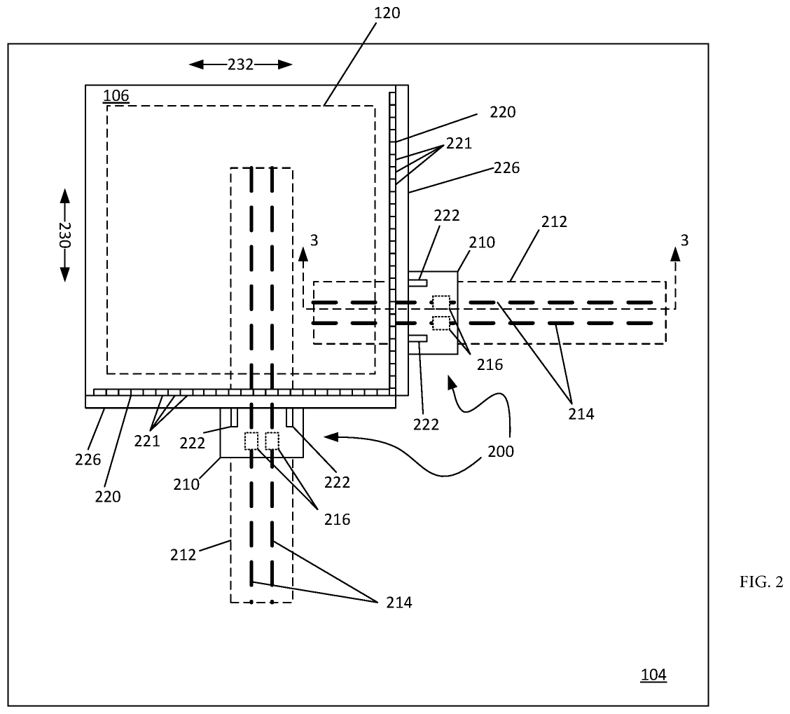

FIG. 2 illustrates one embodiment of the present invention, which is a traveler mechanism 200 for accurately positioning a substrate S on a stage 106 relative to a projection camera 110 or other mechanism that exposes, inspects, views, measures, or otherwise acts upon a substrate S. Note that in FIG. 2, the projection camera 110 and supporting structure have been omitted for the sake of clarity.

A traveler mechanism according to the present invention allows for a large format lithography and other operations to be performed on panels and other substrates. The large travel dimensions in scan and travel directions may exceed 2 meters. This is accomplished by providing one or more trucks 210 that travel with a planar stage over a stationary platen in the stage's scan and travel directions. The truck includes a mechanism that allows travel of the truck relative to the stage along an axis other than the one in which the truck provides position information. The truck 210 runs upon a rail 212 that includes at least one linear encoder 214 to provide a position of the truck relative to the platen 104. The position of the truck is read by a read head 216 secured to the truck 210 itself. The truck also includes a mechanism for determining a distance between the stage 106 and the truck.

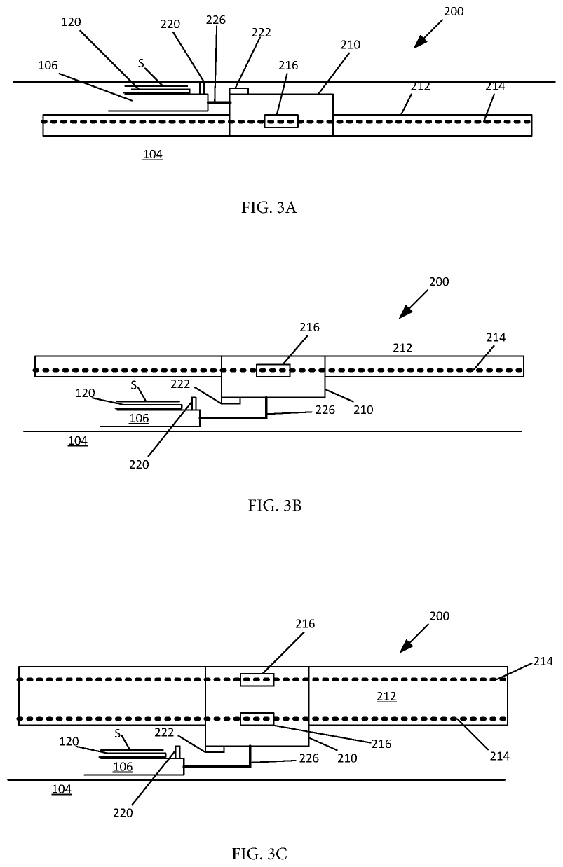

As can be seen in FIG. 2, a platen 104 and stage 106 may include more than one traveler mechanism 200. Each traveler mechanism 200 provides a position along a defined axis relative to the platen 104. Note that cameras and other apparatus that may be addressed to a substrate are generally localized within the same coordinate system as the platen 104. In this way the position of a substrate may be determined relative to the projection cameras/apparatuses used to modify the substrate. The sensitive axis of each traveler mechanism 200 is defined by the rail or track 212 upon which the truck or block 210 rides. The truck 210 and rail 212 combination may be formed using a linear bearing or an air bearing of a suitable sort. The length of the rail 212 defines the travel distance of the traveler mechanism 200. One or more scales for measuring position such as linear encoders 214 are included with the rail 212. The linear encoders 214 may be of an optical or electromagnetic type. Generally, the positioning resolution of the system will be relatively precise, being in the range of ±200 nm over the entire range of travel, which may be more than two meters. One or more read heads 216 are secured to the truck 210 and ride along the linear encoders 214 to determine the position of the truck 210 relative to the platen 104. The rails 212 may be separate structures that are secured to the platen 104 between the platen 104 and the stage 106. The rails 212 may also be formed as part of the platen 104 itself by insetting some or all of the structure of the rail 212 into the platen 104. In another embodiment, the rails 212 are positioned and fixed above the stage 106. In this embodiment, the rails 212 are coupled to the bridge support 108. The supporting structure is omitted for clarity. The position of the rails 212 relative to the platen 104 is shown more clearly in FIGS. 3A and 3B.

At the edge of stage 106, generally perpendicular to the axes of the traveler mechanisms 200 are found reference surfaces 220. Surfaces 220 are positioned so that distance sensors 222 that are secured to truck 210 will be able to sense a distance between the truck 210 and the stage 106. Surfaces 220 may be solid, however as it is desired for these surfaces 220 to be as flat as possible so that measurements are as precise as possible, it must be acknowledged that solid surfaces 220 are quite expensive when their length may exceed 2 meters. In a preferred embodiment, the surfaces 220 are made of individual segments 221. Segments 221 are more easily flat and while there may be variation in the placement of segments 221 to form surfaces 220, such variation may be minimized and/or calibrated such that error in localization is minimized. The distance sensors 222 may be capacitive, interferometric, chromatic confocal, laser triangulation or similar distance sensors. Note that since the distance to be measured by sensors 222 is relatively short, interferometric sensors may be successfully employed in this setting. In situations where the surfaces 220 are essentially planar, only a single sensor 222 is required to measure the variation in distance between the stage 106 and the truck 210. Where one is interested in measuring any angular variation between the stage 106 and the truck 210, one will need to include two sensors 222, the difference between the measurements reported by the two sensors 222 being used to determined angle between the truck 210 and the stage 106.

Since the truck 210 moves only along the rails 212, to sense the position of the stage 106 along the sensitive axis of the traveler mechanism it is necessary to couple the truck 210 to the stage 106. To permit relative translation between a truck 210 and the stage along a non-sensitive or ancillary axis that is often perpendicular to the rails 212, a linear coupler 226 is used to secure the truck 210 to the stage 106. When the stage 106 moves along an axis described by arrow 230, the truck 210 of the left traveler mechanism 200 will move in close conformity with the stage along its rails 212. The linear encoders 214 and read heads 216 will give the position of the truck 210 relative to the platen 104. The distance sensors 222 on the truck of the left traveler mechanism 220 provide the position of the stage 106 relative to the truck 210. Combining the measurements obtained from the read heads 216 and the distance sensors 222 provides the information necessary to accurately localize the stage 104 relative to the platen 106 along the axis of the left traveler mechanism 200. While the stage 106 moves along the axis 230, truck 210 of the right traveler mechanism 200 does not move relative to its rails 212. Rather, the truck 210 remains stationary while the coupler 226 allows the stage 106 to move relative to the truck 210. The inverse applies when the stage 106 moves along an axis defined by arrow 232. In this manner, the stage 106 may be easily localized in the plane defined by the platen 104.

In some embodiments, such as where multiple segments 221 form the surfaces 220, two or more sensors 222 may be desirable. For example, two sensors 222 are emplaced on a truck 210 as seen in FIG. 2. This allows for the measurement of an angle between the stage 106 and the truck 210, providing that each of the segments 221 are coplanar. Two sensors 222 may also be used to measure the distance between the stage 106 and the truck 210 for each individual segment 221. In this embodiment, the respective sensors 222 measure variation in the distance between the truck 210 and the stage 106 from what a read head 216 reports. This distance is nominally the same at all times. However, backlash may allow this distance to vary. Where the stage 106 moves relative to a truck 210 (e.g. relative motion along axis 230) such that different segments 221 are successively presented to sensors 222, variation in the placement of segments 221 can lead to uncertainty in the readings. In this arrangement, one sensor 222 will precede or lead the remaining, trailing sensor 222 relative to the stage 106. A single sensor 222 translating between variously positioned segments 221 will report a change in the stage/truck distance that is in truth a variation in position between the segments 221. Spacing multiple sensors 222 so that they address successive segments 221 allows variation between the respective sensors 222 to be measured and used as a base line or calibration. Further, even without a baseline, a trailing sensor 222 may retain the position of a given segment 221 even as a leading sensor 222 addresses an adjacent segment 221. Changes in the position reported by the trailing sensor 222 will represent changes in the stage/truck position whereas differences in position reported by the leading and trailing sensors can be attributed to misalignment of the segments. In one embodiment, the spacing between leading and trailing sensors 222 is slightly less than the pitch at which the segments 221 are spaced. This helps ensure that the trailing sensor remains on the current segment 221 for a period sufficient for the position of the segment addressed by the leading sensor 222 to be recorded and accommodated. The sensors 222 may be spaced to skip segments 221 and may be spaced at any suitable pitch, including at a pitch that is slightly less than the pitch of the segments 221 multiplied by any desired number of segments n from one to the total number of segments in a surface 220.

Additional sensors 222 may be used to measure the angle of each segment 221 in a surface 220. In this embodiment, pairs of sensors 222 are addressed to a given segment 221 to measure its angle as well as the stage/truck distance. As will be appreciated, two pairs of sensors 222 are employed as described as with the two sensors 222 shown mounted on trucks 210 in FIG. 2. This permits multiple segments 221 of surface 220 to be localized in their XYO orientation relative to the truck 210. As will be appreciated, using any suitable number of sensors 220, one may accurately position the segments 221 for use as a calibration reference. This will reduce the need for multiple sensors 222 and will also make the positioning system much more fault tolerant should there by a discrepancy with a reading from the read heads 216.

While the embodiments shown here have the rails 212 of the traveler mechanisms 200 arranged essentially perpendicularly to one another, this is not required. Any complementary relationship or angle between the traveler mechanisms 200 that permit the stage 106 to be localized relative to the platen 104 may be used. Note that the axes defined by the rails 212 will still define a plane that is parallel to the plane in which stage 106 travels.

The couplings 226 are in some embodiments unpowered linear bearings, though air bearings such as pre-stressed air bearings may be used. In order to move the stage 106 a bit faster relative to the platen 104, it may be desirable to include a linear actuator (not shown) of some sort between the truck 210 and the rails 212 of each traveler mechanism 200. In this embodiment, the linear couplings 226 would be omitted as the linear actuator would be driven to maintain a nominal distance between the truck 210 and the stage 106. As expected, the read heads 216 and linear encoders 214 will still indicate the position of the truck 210 relative to the platen 104. Driving the trucks 210 along a nominal path that the stage 106 will follow allows the distance sensors 222 to measure the distance between the truck 210 and the stage 106, providing the information needed to accurately localize the stage 106 relative to the platen 104. The addition of the linear actuator and omission of the linear coupling 226 reduces the inertia of the stage 106 and permits the stage 106 to accelerate at higher rates.

FIG. 3A is a side elevation of how a traveler mechanism 200 with its rails 212 positioned between the stage 106 and platen 104 might be arranged. Note that the traveler mechanism 200 in the figure includes a linear coupler 226, though as indicated above, this may be omitted in favor of a linear actuator that moves truck 210 along track 212 to follow the stage 106. FIG. 3B is another side elevation of a traveler mechanism 200 but with the rails 212 positioned above the stage 106. Again, the optional linear coupler 226 is shown in this embodiment. The linear coupler 226 in FIG. 3B would be positioned to allow the distance sensor 222 to address the reference surface 220.

FIG. 3C shows a variation on the embodiment illustrated in FIG. 3B. In this embodiment, at least one additional linear encoder 214′ is provided. Linear encoder 214′ is vertically separated from the pictured linear encoder 214. In normal operation the read heads 214, 214′ should output substantially identical positions as they linear encoders are nominally parallel to one another. But, where the truck 210 is pitched upward or downward as it moves along rail 212, the read heads 214, 214′ will output slightly different values. This differential measurement, along with the known distance between the rails linear encoders 214, 214′ allow one to compute the amount of pitch the truck 210 is experiencing. Any measurable pitch at the truck 210 is considered to be an aberrant condition that is to be minimized or omitted, if possible. Pitch may come from a number of sources, including aparallel rails 212 or linear encoders 214, 214′. Pitch may also be derived from the motion of the stage 106 over an non-flat base 104. This latter source of pitch may be transmitted through the coupler 226 to the truck 210. The measured pitch values are, in some embodiments, used to modify the position of a reticle 134 by adjusting the reticle chuck 132. In this way aberration due to pitch may be minimized.

FIG. 4A is a plan schematic view showing an example of the extent of the travel of a stage 106 relative to a platen 104 for a system in which only a single projection camera 110 is employed. It is to be understood that projection camera 110 may be replaced by an inspection, metrology, or other process tool or mechanism that acts upon a substrate secured to stage 106. In FIG. 4B, there is shown an example of the extent of the travel of a stage 106 relative to a platen 104 where two projection cameras 110 are employed. Generally, the amount of travel required to address a substrate S to a single projection camera 110 is greater than it would be to address a substrate S to two projection cameras 110.

In building a machine that incorporates a traveler mechanisms 200, it is desirable to calibrate the traveler mechanism 200 before use. In one instance, a distance sensor such as interferometer (not shown) may be placed on or near the base 102 of the system 100. It is a good idea to not place the interferometer on the platen 104 as the stage 106 may come into contact with the interferometer. A mirror (also not shown) is placed on the truck 210 to measure the position of the truck relative to the base 102 and platen 104 that is fixed thereto. Each truck 210 is moved through its entire range of motion and its position relative to the base 102 is recorded. Note that in each traveler mechanism 200, there are illustrated two linear encoders and associated read heads. This is to provide a means to measure an angular position of the stage 106 in addition to its position in a Cartesian coordinate plane. This angular position may be corrected using the forcer motors (not shown) or may be induced in order to angularly align a substrate S to a projection camera 110.

Having calibrated the position of each truck 210 relative to the base/platen, the system 100 may be ready for use. Additional calibration may be helpful however. Using the interferometer or another useful distance sensor, an operator will preferably calibrate the output of the distance sensors 222 relative to the reference surface 220. Using a calibration target formed directly on the stage 106 or on the chuck 120, the position of the projection camera 110 relative to the stage 106 may be calibrated. Of course, one will also want to calibrate the position of the stage 106 to the position of the chuck 120. Using the aforementioned calibrations, one is able to generate a transform that is used with the output of the read heads 216 and the position sensors 222 to accurately position a substrate S relative to the projection camera 110. When calibrations are complete the distance sensor, such as an interferometer, used in the calibration is removed from the system 100.

One or more embodiments are described as follows:

1. A traveler mechanism for localizing a stage comprising:
a rail, the rail having a linear encoder;
a truck that travels on the rail, the truck having a read head that indicates a nominal position of the truck along the rail;
a linear coupler that connects the traveler to the stage such that when the stage moves in a direction parallel to the rail, the linear coupler causes the truck to move along the rail and when the stage moves in a direction transverse to the rail, the stage will be able to move relative to the truck; and,
a reference surface positioned on the stage and opposing at least one distance sensor positioned on the truck, the position reported by the read head and the nominal distance reported by the distance sensors are combined to localize the stage.
   2. The traveler mechanism for localizing a stage of clause 1 further comprising at least two distance sensors on the truck, a difference between the distances reported by the distance sensors being used to compute an angle of the stage relative to the truck.
   3. The traveler mechanism for localizing a stage of clause 1 wherein the reference surface comprises a plurality of individual segments positioned to form a nominally planar reference surface.
   4. The traveler mechanism for localizing a stage of clause 3 further comprising at least two distance sensors on the truck, the at least two distance sensors on the truck having a spacing therebetween that addresses the at least two distances sensors to spaced apart segments of the reference surface.
   5. The traveler mechanism for localizing a stage of clause 3 further comprising at least two pairs of distance sensors on the truck, each of the at least two pairs of distance sensors on the truck having a spacing between the individual distance sensors that is less than the width of a segment of the planar reference surface, the at least two pairs of distance sensors having a spacing therebetween that addresses the at least two pairs of distance sensors to spaced apart segments of the reference surface.
   6. The traveler mechanism for localizing a stage of clause 1 wherein the rail is positioned above the stage.
   7. The traveler mechanism for localizing a stage of clause 1 wherein the rail is positioned below the stage.
   8. The traveler mechanism for localizing a stage of clause 1 wherein the stage moves relative to a base, the stage being supported above the base by one of an air bearing mechanism, a mechanical bearing mechanism, and an electromagnetic bearing mechanism.
   9. A positioning mechanism for localizing a stage comprising:
a plurality of tracks, each of the plurality of tracks having a scale;
a plurality of blocks, each of the plurality of blocks being arranged to travel on one of the tracks, each of the plurality of blocks having a sensor that indicates a nominal position of a block along its respective track by reading a position from the scale;
a plurality of connectors, each connector coupling one of the plurality of blocks to the stage such that when the stage moves in a direction parallel to one of the plurality of tracks, the connector causes the block associated with the track in question to move along the track and when the stage moves in a direction transverse to the track in question, the stage will be able to move relative to the block;
a reference surface positioned on the stage and opposing at least one distance sensor positioned on each of the plurality of blocks, the position reported by the sensors directed to scales of each track and the nominal distance reported by each of the distance sensors being combined to localize the stage.
   10. The positioning mechanism for localizing a stage of clause 9 wherein at least two of the plurality of tracks are set perpendicular to one another.
   11. The positioning mechanism for localizing a stage of clause 9 wherein the track is positioned above the stage.
   12. The positioning mechanism for localizing a stage of clause 9 wherein the track is positioned below the stage.
   13. A mechanism for localizing a stage comprising:
a rail, the rail having a linear encoder;
a truck that travels on the rail, the truck having a read head that indicates a nominal position of the truck along the rail;
a drive coupled between the truck and the rail, the drive being operated to maintain a nominal distance between the stage and the truck as the stage moves along an axis defined by the rail, the
a reference surface positioned on the stage and opposing at least one distance sensor positioned on the truck, the position reported by the read head and the nominal distance reported by the distance sensors are combined to localize the stage.
   14. The mechanism for localizing a stage of clause 13 further comprising at least two distance sensors on the truck, a difference between the distances reported by the distance sensors being used to compute an angle of the stage relative to the truck.
   15. The mechanism for localizing a stage of clause 13 wherein the reference surface comprises a plurality of individual segments positioned to form a nominally planar reference surface.
   16. The mechanism for localizing a stage of clause 15 further comprising at least two distance sensors on the truck, the at least two distance sensors on the truck having a spacing therebetween that addresses the at least two distances sensors to spaced apart segments of the reference surface.
   17. The mechanism for localizing a stage of clause 15 further comprising at least two pairs of distance sensors on the truck, each of the at least two pairs of distance sensors on the truck having a spacing between the individual distance sensors that is less than the width of a segment of the planar reference surface, the at least two pairs of distance sensors having a spacing therebetween that addresses the at least two pairs of distance sensors to spaced apart segments of the reference surface.
   18. The mechanism for localizing a stage of clause 13 wherein the rail is positioned above the stage.
   19. The mechanism for localizing a stage of clause 13 wherein the rail is positioned below the stage.
   20. The mechanism for localizing a stage of clause 13 wherein the stage moves relative to a base, the stage being supported above the base by one of an air bearing mechanism, a mechanical bearing mechanism, and an electromagnetic bearing mechanism.
   21. A apparatus for localizing a stage wherein the stage moves in a plane and is localized along at least two axes that are substantially parallel to the plane in which the stage moves, the apparatus comprising:

a mechanism for determining a location along an axis comprising:
a rail, the rail having a linear encoder;
a truck that travels on the rail, the truck having a read head that indicates a nominal position of the truck along the rail;
a linear coupler that connects the traveler to the stage such that when the stage moves in a direction parallel to the rail, the linear coupler causes the truck to move along the rail and when the stage moves in a direction transverse to the rail, the stage will be able to move relative to the truck;
a reference surface positioned on the stage and opposing at least one distance sensor positioned on the truck, the position reported by the read head and the nominal distance reported by the distance sensors are combined to localize the stage; and,

wherein the apparatus includes at least one mechanism for each of the at least two axes.

### CONCLUSION

Although specific embodiments of the present invention have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

1. A traveler mechanism for localizing a stage comprising:
a rail, the rail having a linear encoder;
a truck that travels on the rail, the truck having a read head that indicates a nominal position of the truck along the rail;
a linear coupler that connects the traveler to the stage such that when the stage moves in a direction parallel to the rail, the linear coupler causes the truck to move along the rail and when the stage moves in a direction transverse to the rail, the stage will be able to move relative to the truck; and,
a reference surface positioned on the stage and opposing at least one distance sensor positioned on the truck, the position reported by the read head and the nominal distance reported by the distance sensors are combined to localize the stage.

2. The traveler mechanism for localizing a stage of claim 1 further comprising at least two distance sensors on the truck, a difference between the distances reported by the distance sensors being used to compute an angle of the stage relative to the truck.

3. The traveler mechanism for localizing a stage of claim 1 wherein the reference surface comprises a plurality of individual segments positioned to form a nominally planar reference surface.

4. The traveler mechanism for localizing a stage of claim 3 further comprising at least two distance sensors on the truck, the at least two distance sensors on the truck having a spacing therebetween that addresses the at least two distances sensors to spaced apart segments of the reference surface.

5. The traveler mechanism for localizing a stage of claim 3 further comprising at least two pairs of distance sensors on the truck, each of the at least two pairs of distance sensors on the truck having a spacing between the individual distance sensors that is less than the width of a segment of the planar reference surface, the at least two pairs of distance sensors having a spacing therebetween that addresses the at least two pairs of distance sensors to spaced apart segments of the reference surface.

6. The traveler mechanism for localizing a stage of claim 1 wherein the rail is positioned above the stage.

7. The traveler mechanism for localizing a stage of claim 1 wherein the rail is positioned below the stage.

8. The traveler mechanism for localizing a stage of claim 1 wherein the stage moves relative to a base, the stage being supported above the base by one of an air bearing mechanism, a mechanical bearing mechanism, and an electromagnetic bearing mechanism.

9. A positioning mechanism for localizing a stage comprising:
a plurality of tracks, each of the plurality of tracks having a scale;
a plurality of blocks, each of the plurality of blocks being arranged to travel on one of the tracks, each of the plurality of blocks having a sensor that indicates a nominal position of a block along its respective track by reading a position from the scale;
a plurality of connectors, each connector coupling one of the plurality of blocks to the stage such that when the stage moves in a direction parallel to one of the plurality of tracks, the connector causes the block associated with the track in question to move along the track and when the stage moves in a direction transverse to the track in question, the stage will be able to move relative to the block;
a reference surface positioned on the stage and opposing at least one distance sensor positioned on each of the plurality of blocks, the position reported by the sensors directed to scales of each track and the nominal distance reported by each of the distance sensors being combined to localize the stage.

10. The positioning mechanism for localizing a stage of claim 9 wherein at least two of the plurality of tracks are set perpendicular to one another.

11. The positioning mechanism for localizing a stage of claim 9 wherein the track is positioned above the stage.

12. The positioning mechanism for localizing a stage of claim 9 wherein the track is positioned below the stage.

13. A mechanism for localizing a stage comprising:
a rail, the rail having a linear encoder;
a truck that travels on the rail, the truck having a read head that indicates a nominal position of the truck along the rail;
a drive coupled between the truck and the rail, the drive being operated to maintain a nominal distance between the stage and the truck as the stage moves along an axis defined by the rail, the
a reference surface positioned on the stage and opposing at least one distance sensor positioned on the truck, the position reported by the read head and the nominal distance reported by the distance sensors are combined to localize the stage.

14. The mechanism for localizing a stage of claim 13 further comprising at least two distance sensors on the truck, a difference between the distances reported by the distance sensors being used to compute an angle of the stage relative to the truck.

15. The mechanism for localizing a stage of claim 13 wherein the reference surface comprises a plurality of individual segments positioned to form a nominally planar reference surface.

16. The mechanism for localizing a stage of claim 15 further comprising at least two distance sensors on the truck, the at least two distance sensors on the truck having a spacing therebetween that addresses the at least two distances sensors to spaced apart segments of the reference surface.

17. The mechanism for localizing a stage of claim 15 further comprising at least two pairs of distance sensors on the truck, each of the at least two pairs of distance sensors on the truck having a spacing between the individual distance sensors that is less than the width of a segment of the planar reference surface, the at least two pairs of distance sensors having a spacing therebetween that addresses the at least two pairs of distance sensors to spaced apart segments of the reference surface.

18. The mechanism for localizing a stage of claim 13 wherein the rail is positioned above the stage.

19. The mechanism for localizing a stage of claim 13 wherein the rail is positioned below the stage.

20. The mechanism for localizing a stage of claim 13 wherein the stage moves relative to a base, the stage being supported above the base by one of an air bearing mechanism, a mechanical bearing mechanism, and an electromagnetic bearing mechanism.

21. (canceled)
